(19) United States
(12) Patent Application Publication
(10) Pub. No.: US 2022/0344970 A1
(43) Pub. Date: Oct. 27, 2022

(54) PRE-LAUNCH ENERGY HARVESTING ON AERODYNAMIC SYSTEMS

(71) Applicant: BAE Systems Information and Electronic Systems Integration Inc., Nashua, NH (US)

(72) Inventors: Maxwell L. Affleck, New Boston, NH (US); Seth D. Baney, Nashua, NH (US); Jason H. Batchelder, Lyndeborough, NH (US)

(73) Assignee: BAE Systems Information and Electronic Systems Integration Inc., Nashua, NH (US)

(21) Appl. No.: 17/238,777

(22) Filed: Apr. 23, 2021

(51) Int. Cl. H02J 50/00; H02J 50/40; H02J 7/00; H02N 2/18; B64D 47/00

(52) U.S. Cl. CPC H02J 50/001; H02J 50/40; H02J 50/005; H02J 7/0042; H02N 2/186; B64D 47/00

(57) ABSTRACT

An energy harvesting system is disclosed that is especially well-suited for use on aerodynamic systems such as guided projectiles or other aerobodies. A series of piezoelectric cantilevers are arranged to capture vibrations from the ambient environment and transduce the mechanical motion from the vibrations into useful electrical energy. The piezoelectric cantilevers can be arranged along different planes from one another to capture different vibrational modes and directions. A power conditioning circuit is included to receive the electrical energy produced by the piezoelectric cantilevers. A storage element coupled to the power conditioning circuit is configured to store charge based on the electrical energy produced by the plurality of piezoelectric cantilever structures. The stored charge can be used to provide low levels of power to certain electrical components on board the aerodynamic system before it has been launched.

### BACKGROUND

Energy storage has always been a limiting factor for powering electronics in various systems. For some systems, traditional energy storage techniques fail to adequately provide power in certain circumstances. For example, aerodynamic systems such as guided missiles or rockets or other such projectiles require an energy storage mechanism that is fully self-contained within the projectile. Such systems often include guidance electronics and other important electrical systems that are powered during flight. However, these systems are not powered before the rocket has launched, which can cause problems with initializing some of the electrical systems. Furthermore, traditional energy storage devices (e.g., batteries) inherently drain over time and need replacement, which is not possible in some systems. Accordingly, there are many non-trivial issues with regards to designing better energy storage systems for use on an aerodynamic system.

### BRIEF DESCRIPTION OF THE DRAWINGS

Features and advantages of embodiments of the claimed subject matter will become apparent as the following Detailed Description proceeds, and upon reference to the Drawings, in which:

FIG. 1 illustrates an example aerodynamic projectile configured with an energy harvesting system, in accordance with an embodiment of the present disclosure.

FIGS. 2A and 2B illustrate different views of an energy harvesting system, in accordance with some embodiments of the present disclosure.

FIG. 3 illustrates a cross-section view of the energy harvesting system of FIGS. 2A and 2B, in accordance with an embodiment of the present disclosure.

FIG. 4 illustrates a block diagram of the components of the energy harvesting system of FIGS. 2A and 2B, which can be used to power various components of an aerodynamic system, in accordance with some embodiments of the present disclosure.

FIGS. 5A and 5B illustrate example configurations of piezoelectric cantilevers within the energy harvesting system of FIGS. 2A and 2B, in accordance with some embodiments of the present disclosure.

FIG. 6 illustrates another example configuration of piezoelectric cantilevers within the energy harvesting system of FIGS. 2A and 2B, in accordance with an embodiment of the present disclosure.

FIGS. 7A and 7B illustrate different views of a single piezoelectric cantilever, in accordance with some embodiments of the present disclosure.

Although the following Detailed Description will proceed with reference being made to illustrative embodiments, many alternatives, modifications, and variations thereof will be apparent in light of this disclosure.

### DETAILED DESCRIPTION

An energy harvesting system is disclosed that is especially well-suited for use on aerodynamic systems such as guided projectiles or other aerobodies. In an embodiment, a series of piezoelectric cantilevers are arranged to capture vibrations from the ambient environment and transduce the mechanical motion from the vibrations into useful electrical energy. This is particularly advantageous for aerodynamic systems to power some of the electrical components, in advance of the system being engaged. For instance, in the case of a launch tube based projectile, the resulting power can be used to power one or more electrical components of the projectile before it has left the launch tube. That is, natural vibrations from the movement of the launch tube as it is in transit (e.g., via movement of an aircraft or ship that includes the launch tube) can be harvested to provide power to portions of the projectile or other aerodynamic system. As used herein, the term “aerodynamic system” refers to any guided or unguided areobody, such as for example, rockets, missiles, high caliber bullets, shells, artillery rounds, or other munitions, as well as any manned or unmanned aircraft (e.g., drone or unmanned aerial vehicle—UAV) or ground vehicle. The piezoelectric cantilevers can be arranged along different planes from one another to capture different vibrational modes and directions. A power conditioning circuit is included to receive the electrical energy produced by the piezoelectric cantilevers. A storage element coupled to the power conditioning circuit is configured to store charge based on the electrical energy produced by the plurality of piezoelectric cantilever structures. In some embodiments, the storage element includes a capacitor or a bank of capacitors. Numerous embodiments and variations will be appreciated in light of this disclosure.

General Overview

As noted above, some electrical components found on aerodynamic systems, such as guidance controllers, inertial measurement units (IMUs), or any volatile memory storage, can benefit by being powered even before the aerodynamic system has launched. For example, an IMU is typically powered shortly after launching the aerodynamic system. However, since the initial environment is very noisy with chaotic vibrations (since the aerodynamic system has been launched), it can take time for the IMU to stabilize itself and begin accurately tracking the movement of the aerodynamic system. In some other examples, data cannot be stored in volatile memory unless it is receiving at least a constant low level of power and guidance controllers cannot receive any updates or changes unless they are powered. Traditional power storage techniques are not practical for use on such aerodynamic systems. Thermal batteries can provide a high amount of power in a short amount of time (e.g., during the flight time of a rocket), but they cannot be relied upon to provide power until after the aerodynamic system has launched (they tend to drain quickly and require replacement). Furthermore, many types of aerodynamic systems can sit in a storage location or within a launch tube for long periods of time before actually being launched, thus making any standard battery-based solutions unreliable.

Accordingly, embodiments herein disclose an energy harvesting system that provides on-demand power using vibrations from the surrounding environment. In some examples, the vibrational energy is received from natural vibrations of a launch tube that contains the aerodynamic system having the energy harvesting system. The launch tube vibrates during transit (e.g., while attached to an aircraft, ship, or ground vehicle) before the aerodynamic system is launched from the launch tube. According to some embodiments, the energy harvesting system includes a plurality of piezoelectric cantilevers arranged along different planes to increase the likelihood of providing the most efficient power output for any given vibration environment, since it may be unknown from which direction the maximum vibrational energy will occur at any given time. A power conditioning circuit along with a storage element is coupled to the plurality of piezoelectric cantilevers to store charge based on the electrical energy produced by the plurality of piezoelectric cantilevers. Any one or more switching circuits coupled to the storage element can be used to bleed or otherwise use the charge from the storage element and power any one or more electrical components on the aerodynamic system before it has been launched.

As noted above, the energy harvesting system may be specifically configured for use on an aerodynamic system in order to provide power to the system before it has been launched or otherwise activated. It may be unknown from which direction the highest order vibrations will occur since the aerodynamic system may be loaded, for example, at various orientations within a launch tube or on a launch pad. Thus, and according to some embodiments, the piezoelectric cantilevers are arranged at different orientations compared to one another to more efficiently capture vibrational energy from various directions. In one example, at least three piezoelectric cantilevers can be arranged in a triangular shape (e.g., orientated along planes with an angle of about 60 degrees between each intersecting plane). In some examples, piezoelectric cantilevers of different lengths and/or with a different mass at the free end are used to capture different vibration frequencies.

According to one example embodiment of the present disclosure, an energy harvesting system configured for use on an aerodynamic system includes a plurality of piezoelectric cantilever structures, a power conditioning circuit, and a storage element coupled to the power conditioning circuit. The power conditioning circuit is configured to receive electrical energy produced by the plurality of piezoelectric cantilever structures, and the storage element is configured to store charge based on the electrical energy produced by the plurality of piezoelectric cantilever structures. The plurality of piezoelectric cantilever structures includes a first piezoelectric cantilever structure disposed within a fuselage of the aerodynamic system and orientated along a first plane, a second piezoelectric cantilever structure disposed within the fuselage of the aerodynamic system and orientated along a second plane different from the first plane, and a third piezoelectric cantilever structure disposed within the fuselage of the aerodynamic system and orientated along a third plane different from the first plane and the second plane.

According to another example embodiment of the present disclosure, an energy harvesting system configured for use on an aerodynamic system includes a barrier disposed within a fuselage of the aerodynamic system, a plurality of piezoelectric cantilever structures arranged adjacent to a first face of the barrier, and a printed circuit board (PCB) disposed on a second face of the barrier opposite from the first face of the barrier. The plurality of piezoelectric cantilever structures are arranged such that a primary deflection vector for each of the plurality of piezoelectric cantilever structures is parallel to the first face of the barrier. The PCB includes a power conditioning circuit and a storage element coupled to the power conditioning circuit. The power conditioning circuit is configured to receive electrical energy produced by the plurality of piezoelectric cantilever structures, and the storage element is configured to store charge based on the electrical energy produced by the plurality of piezoelectric cantilever structures.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous.

Aerodynamic System Overview

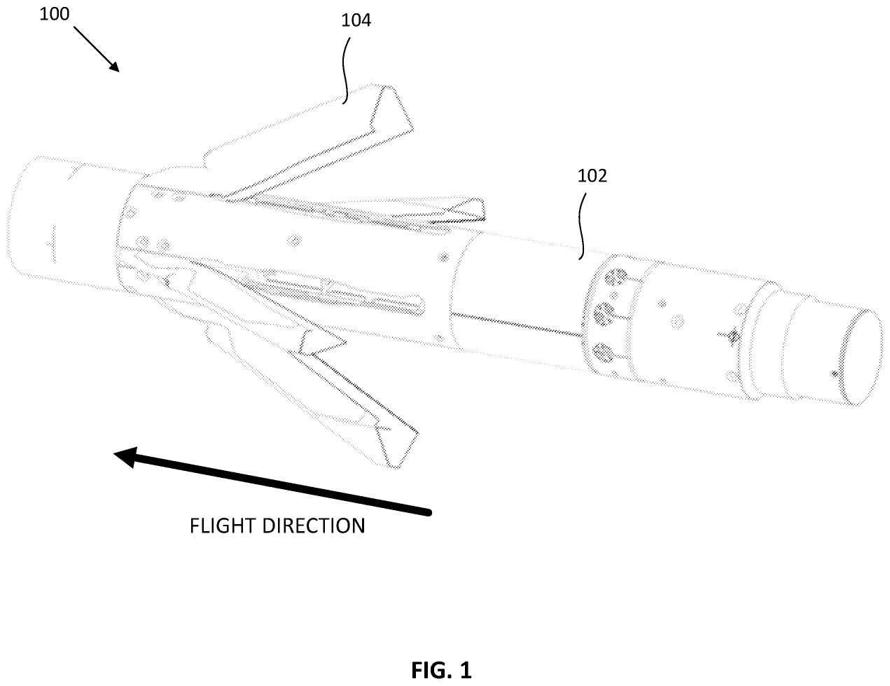

FIG. 1 illustrates an example of an aerodynamic system 100. As previously noted, the aerodynamic system 100 may be any caliber or type of projectile that houses electrical components, such as RF communication components, processor(s) for carrying out mission-specific commands, or other guidance electronics. In one example, aerodynamic system 100 is a guided munition, such as a guided rocket, but other applications will be apparent.

According to some embodiments, aerodynamic system 100 includes a fuselage 102 that acts as an outer shell or hull to contain the various elements of aerodynamic system 100. In some examples, fuselage 102 has a cylindrical shape yielding a substantially circular cross-section. Fuselage 102 may have a diameter between about 2.0 inches and 3.5 inches. Small dimensions of rounds less than 2.0 inches in diameter is another example. In a further example, larger diameter missiles such as those with larger payloads or configured for long distance travel may have diameters that exceed 3.5 inches. Fuselage 102 may have any number of configurations and may be implemented from any number of materials. For instance, fuselage 102 may be a cylinder of light weight material such as titanium or a polymer composite. Fuselage 102 may be one monolithic piece of material or may be multiple pieces that are individually formed and then joined in a subsequent process. In the latter case, multiple materials may be used, such as an aluminum end cap, a titanium central body portion, and a polymeric nose cone. In a more general sense, fuselage 102 is not intended to be limited to any particular design or configuration.

Aerodynamic system 100 may include one or more wings 104. The tilt angle and general orientation of each of wings 104 can be independently controlled via a guidance system on board aerodynamic system 100 to change the flight path.

According to some embodiments, aerodynamic system 100 may be loaded into a launch tube or launch pad for secure transport until the moment that it is launched. While sitting in the launch tube or on a launch pad, natural vibrations from the environment will be present (e.g., an aerodynamic system in a lunch tube or on a launch pad on an aircraft, ship, or ground vehicle will experience vibrations as the aircraft, ship, or ground vehicle moves or idles. In the case of the ship, natural bobbing movements by being in the water can produce vibrations experienced by the aerodynamic system.

Energy Harvesting System Overview

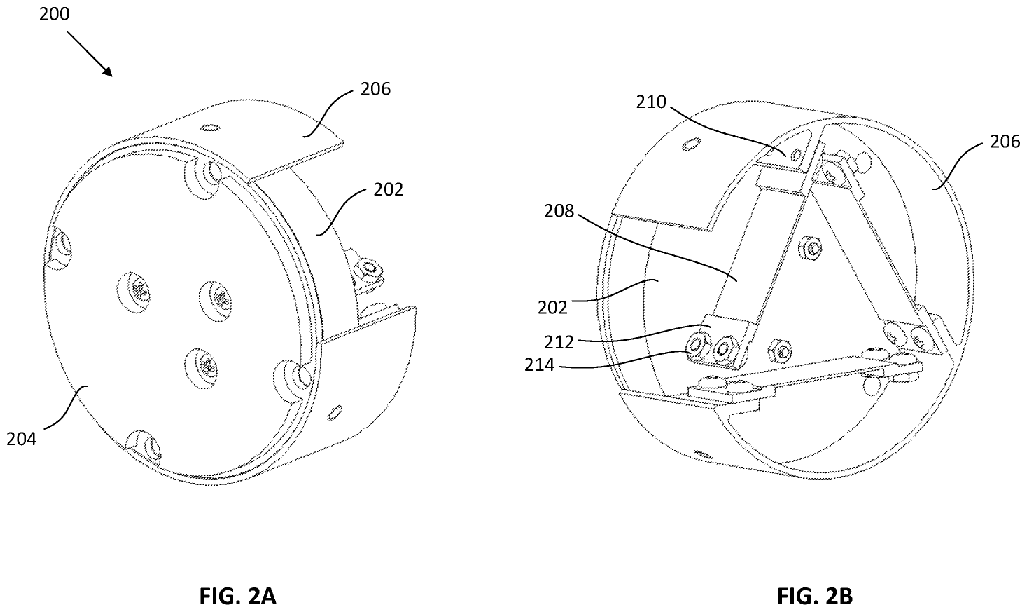

FIGS. 2A and 2B illustrate different views of an example energy harvesting system 200 that can be used on board aerodynamic system 100 to provide power to any one or more electrical components. Energy harvesting system 200 may be a stand-alone power generation system, or it may be one portion of a larger power generation system on board aerodynamic system 100 that provides power to any one or more electrical components. The specific shapes and relative sizes shown in the illustrations are provided as one example embodiment and to clearly show the various components. The illustrations may not be drawn to scale.

FIG. 2A illustrates energy harvesting system 200 from a first angle that shows a barrier 202, a printed circuit board (PCB) 204 coupled to one face of barrier 202, and a collar 206 attached around an outer perimeter of barrier 202. FIG. 2B illustrates energy harvesting system 200 from another angle showing an opposite side of barrier 202, collar 206, and a plurality of piezoelectric cantilevers 208. Barrier 202 may be appropriately shaped and sized to fit within fuselage 102 of aerodynamic system 100. For example, for a cylindrical fuselage having a circular cross-section, barrier 202 may have a circular shape to substantially fill a circular cross-section region within fuselage 102. Barrier 202 may be formed from any rigid material. In some examples, barrier 202 is electrically non-conducting.

Collar 206 may be formed from the same material as barrier 202 and wraps around all, or at least a portion of, an outer perimeter of barrier 202. Collar 206 and barrier 202 may be formed from the same piece of machined material. In the illustrated embodiment where barrier 202 is circular, collar 206 wraps around a circumference of barrier 202. According to some embodiments, collar 206 provides a surface to couple to a fixed end 210 of each of one or more of piezoelectric cantilevers 208 as shown in FIG. 2B.

PCB 204 may be any circuit board material having any number of layers. In one example, PCB 204 is an FR-4 circuit board. According to some embodiments, PCB 204 includes one or more electrical components configured to condition and store the electrical energy generated by piezoelectric cantilevers 208. For example, PCB 204 includes at least a power conditioning circuit and a storage element. In some embodiments, PCB 204 includes other electrical components used to provide guidance, tracking, and/or RF communication capability to the aerodynamic system.

According to some embodiments, each of the piezoelectric cantilevers 208 includes a fixed end 210 coupled to a portion of collar 206, and a free end 212. The maximum deflection amplitude of any given piezoelectric cantilever 208 is located at free end 212. According to some embodiments, each of the piezoelectric cantilevers 208 includes two layers of piezoelectric material and a layer of non-piezoelectric material sandwiched between the two layers of piezoelectric material. Voltage is created due to the strain difference generated between the two layers of piezoelectric material (e.g., tensile strain vs compressive strain) as the cantilever vibrates. In some other embodiments, each of the piezoelectric cantilevers 208 includes a single layer of piezoelectric material sandwiched between doped semiconductor layers of opposite type (e.g., one layer is n-doped while the other is p-doped). The piezoelectric material used in any embodiment may include lead zirconate titanate (PZT). According to some embodiments, wires are electrically coupled between PCB 204 and each of the piezoelectric layers in a given piezoelectric cantilever 208 in order to provide the electrical current output from the given piezoelectric cantilever 208 to one or more of the components on PCB 204. In some other embodiments, electrical connections are made to each of the piezoelectric layers in a given piezoelectric cantilever 208 at the fixed end 210 such that current passes from the given piezoelectric cantilever 208 to PCB 204 via conductive elements within or against collar 206.

Each of piezoelectric cantilevers 208 has a fixed length and a fixed mass 214 affixed to free end 212 that are tailored to maximally deflect at a given resonant frequency. According to some embodiments, the lengths and masses 214 used for each of piezoelectric cantilevers 208 are chosen to yield a resonant frequency that matches or is close to anticipated vibrational frequencies of the surrounding environment. In this way, the piezoelectric cantilevers 208 may be tailored to provide maximum deflection (and thus maximum power output) for a given vibrational environment, such as within a launch tube or on a launch pad.

According to some embodiments, mass 214 represent screws of selectable size and weight that can be twisted onto free end 212 of a given piezoelectric cantilever 208 in order to adjust the mass affixed to free end 212. Any other mass types can be used as well and affixed to free end 212 using any other known means, such as by using an epoxy or adhesive.

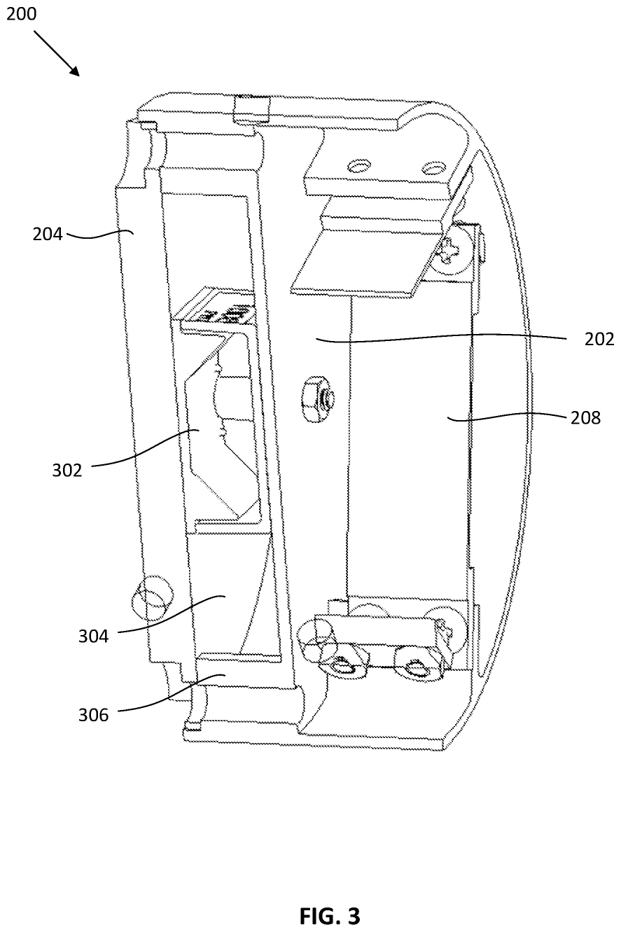

FIG. 3 illustrates an example cross-section view through a portion of energy harvesting system 200. According to some embodiments, an inertial measurement unit (IMU) 302 is coupled to PCB 204 and provides the current orientation and/or speed of the aerodynamic system. Controllers onboard the aerodynamic system may use the output from IMU 302 to perform guidance and/or tracking operations. As noted above, PCB 204 may include one or more storage elements designed to store charge associated with the power produced by piezoelectric cantilevers 208, and this charge in turn may be used to provide low levels of power to certain critical electrical components, such as IMU 302, before the aerodynamic system has been launched. In some embodiments, IMU 302 includes one or more microelectromechanical systems (MEMS) such as accelerometers, gyroscopes, and/or magnetometers.

In some embodiments, IMU 302 is disposed within a cavity 304 between PCB 204 and barrier 202. The cavity may be formed by coupling PCB 204 to a raised structure 306 that extends away from barrier 202. In some embodiments, raised structure 306 and barrier 202 are formed as one piece (e.g., same monolithic material), such that PCB 204 may still be considered coupled to one face of barrier 202 while piezoelectric cantilevers 208 are arranged adjacent to the opposite face of barrier 202. In some embodiments, raised structure 306 is an extension of barrier 202.

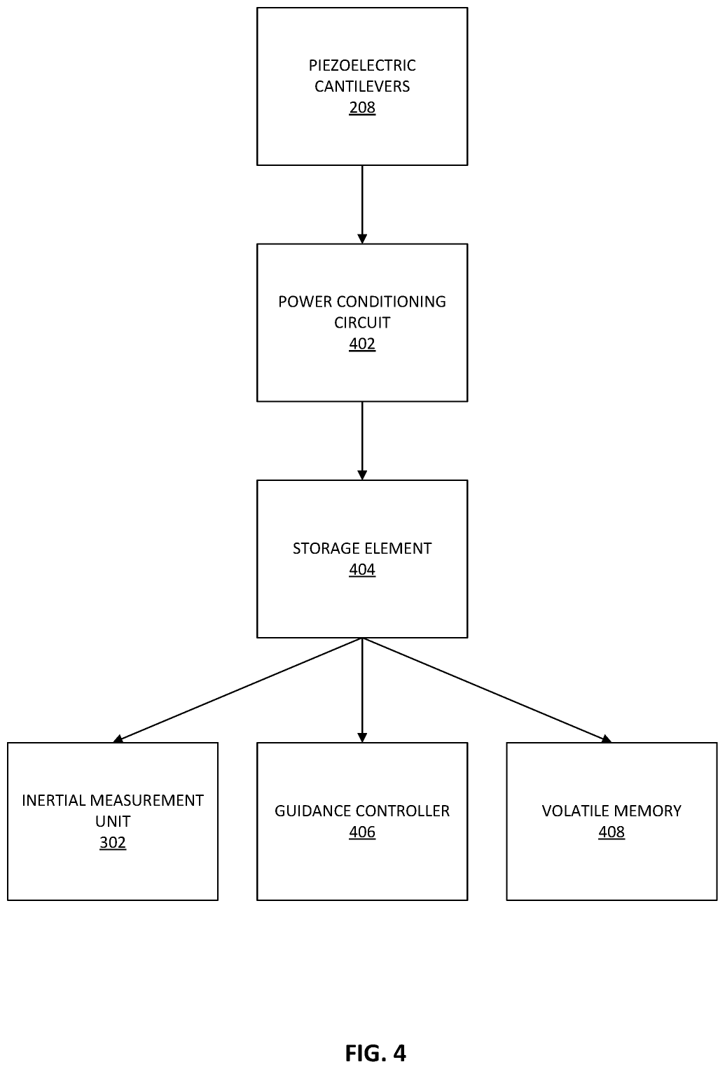

FIG. 4 illustrates a block diagram of various components of energy harvesting system 200 along with various other electrical components of the aerodynamic system that can be powered using energy harvesting system 200. According to some embodiments, plurality of piezoelectric cantilevers 208 are designed to harvest vibrational energy from the environment and transduce the mechanical movement of the vibrating cantilevers into electrical energy that is received by a power conditioning circuit 402.

In some embodiments, power conditioning circuit 402 is arranged on PCB 204. Power conditioning circuit may include any number of voltage regulators and/or envelop detectors. In some embodiments, power conditioning circuit 402 receives an alternating current (AC) signal output from each of the plurality of piezoelectric cantilevers 208 and converts it to a direct current (DC) voltage signal.

According to some embodiments, the DC voltage output from power conditioning circuit 402 is received by a storage element 404. In some embodiments, storage element 404 is also arranged on PCB 204. Storage element 404 may represent a single capacitor, a bank of capacitors, or any other energy storage structure. Storage element 404 stores charge based on the received DC voltage signal from power conditioning circuit 402, according to some embodiments. This charge may be used to provide low levels of power to certain other electrical components on board the aerodynamic system.

According to some embodiments, built-up charge in storage element 404 is released to provide current to one or more different components, such as IMU 302, a guidance controller 406, and/or volatile memory 408. One or more switching circuits can be used to control when to draw current from storage element 404 and/or which component to power with the drawn current. As noted above, guidance controller 406 can use the received current to initialize certain functions and/or a geolocation of the aerodynamic system before the aerodynamic system has been launched. Volatile memory 408 may be provided with certain mission-critical data that can only be accessed while receiving power for security reasons.

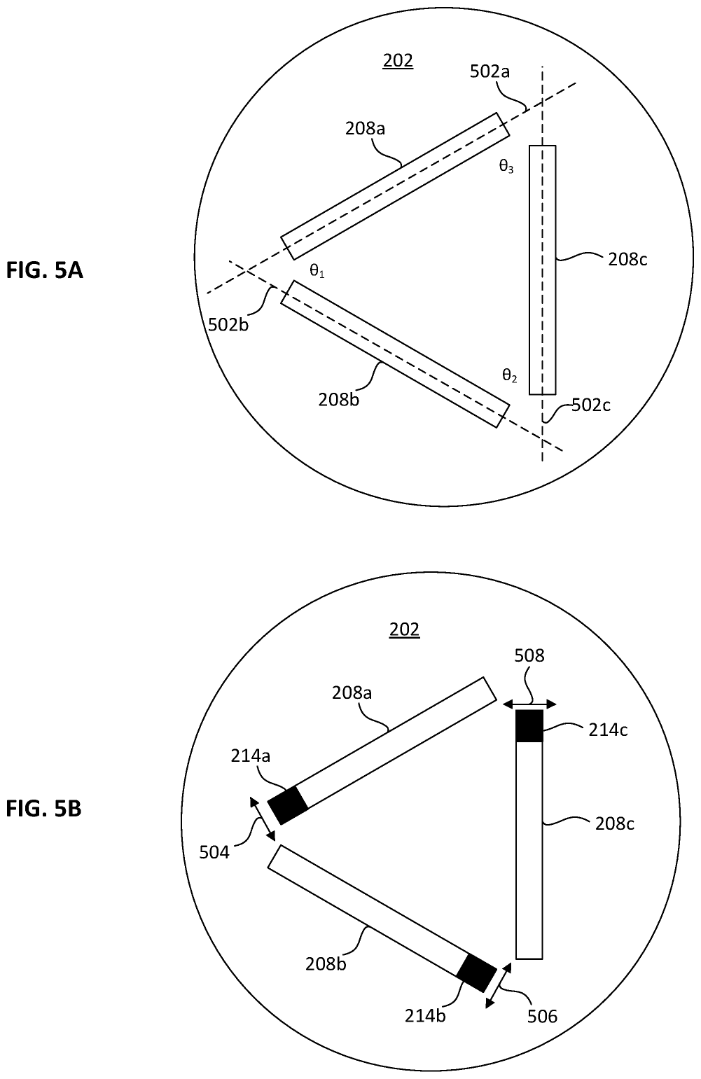

FIG. 5A illustrates a top-down view of barrier 202 with a plurality of piezoelectric cantilevers 208a-208c arranged adjacent to a face of barrier 202. Although only three cantilevers are shown in this example, it should be understood that any number of piezoelectric cantilevers can be provided to capture various vibrational modes and/or directions and the description provided herein with regards to three cantilevers could apply to any number of cantilevers. In some embodiments, piezoelectric cantilevers 208a-208c are each oriented along a different plane. For example, as illustrated in FIG. 5A, each of piezoelectric cantilevers 208a-208c is oriented along a corresponding plane 502a-502c, such that the length of each of piezoelectric cantilevers 208a-208c runs parallel along its corresponding plane 502a-502c. The piezoelectric cantilevers 208a-208c may be arranged in a triangular shape such that an angle θ₁ between a first plane 502a and a second plane 502b is around 60 degrees, an angle θ₂ between second plane 502b and a third plane 502c is around 60 degrees, and an angle θ₃ between third plane 502c and first plane 502a is around 60 degrees. Planes 502a-502c do not need to form a closed shape, like the triangular shape illustrated in FIG. 5A. For example, piezoelectric cantilevers 208a-208c may be arranged such that planes 502a-502c intersect at a single point, or two or more of the piezoelectric cantilevers 208a-208c could be parallel to each other.

FIG. 5B illustrates a primary deflection vector for each of piezoelectric cantilevers 208a-208c, according to some embodiments. As discussed above with reference to FIG. 2B, each of cantilevers 208a-208c includes a corresponding mass 214a-214c at its free end to affect the resonant frequency of the cantilever. Piezoelectric cantilever 208a has a primary deflection vector 504 that is parallel to the surface of barrier 202. Similarly, piezoelectric cantilever 208b has a primary deflection vector 506 that is parallel to the surface of barrier 202 and piezoelectric cantilever 208c has a primary deflection vector 508 that is parallel to the surface of barrier 202. While any number of other deflection modes are possible, primary deflection vectors 504, 506, and 508 represent the lowest order deflection mode that generates the highest amount of bending, and thus the highest voltage output from the piezoelectric material in each of piezoelectric cantilevers 208a-208c.

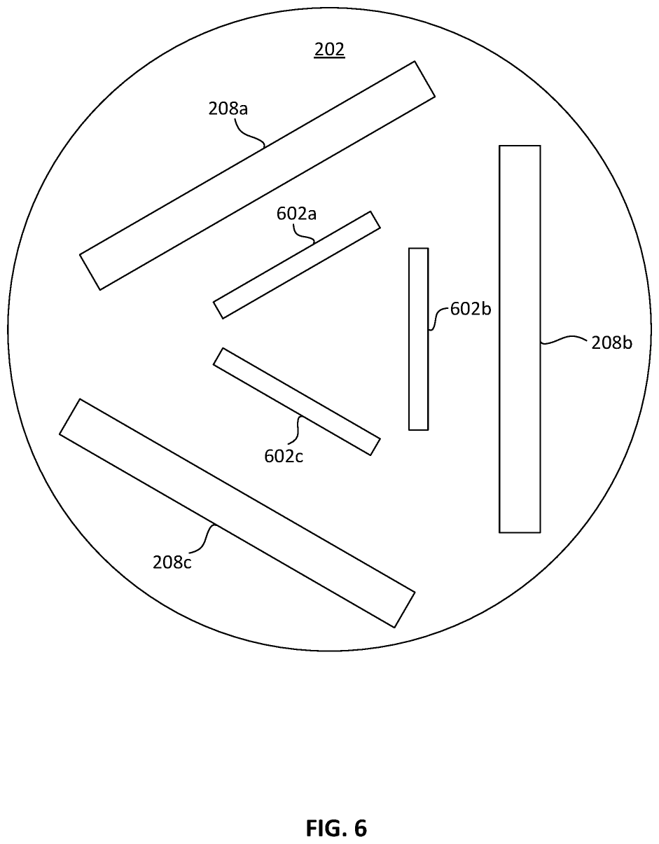

FIG. 6 illustrates a top-down view of barrier 202 with another example arrangement of piezoelectric cantilevers. According to an embodiment, a first plurality of piezoelectric cantilevers 208a-208c are arranged adjacent to a face of barrier 202 along with a second plurality of piezoelectric cantilevers 602a-602c also arranged adjacent to the face of barrier 202. First plurality of piezoelectric cantilevers 208a-208c each has a first length while second plurality of piezoelectric cantilevers 602a-602c each has a second length that may be shorter than the first length. Accordingly, second plurality of piezoelectric cantilevers 602a-602c may be arranged within a space defined by the locations of first plurality of piezoelectric cantilevers 208a-208c, as illustrated in FIG. 6.

Using cantilevers with a smaller length allows for more efficient transduction of higher frequency vibrations and/or lower amplitude vibrations compared to cantilevers having a longer length. Any number of differently sized cantilevers can be arranged adjacent to the face of barrier 202 to capture vibrational energy. According to some embodiments, and as illustrated in FIG. 6, second plurality of piezoelectric cantilevers 602a-602c are arranged in the same shape as first plurality of piezoelectric cantilevers 208a-208c. In some other embodiments, second plurality of piezoelectric cantilevers 602a-602c are arranged in a different shape compared to first plurality of piezoelectric cantilevers 208a-208c.

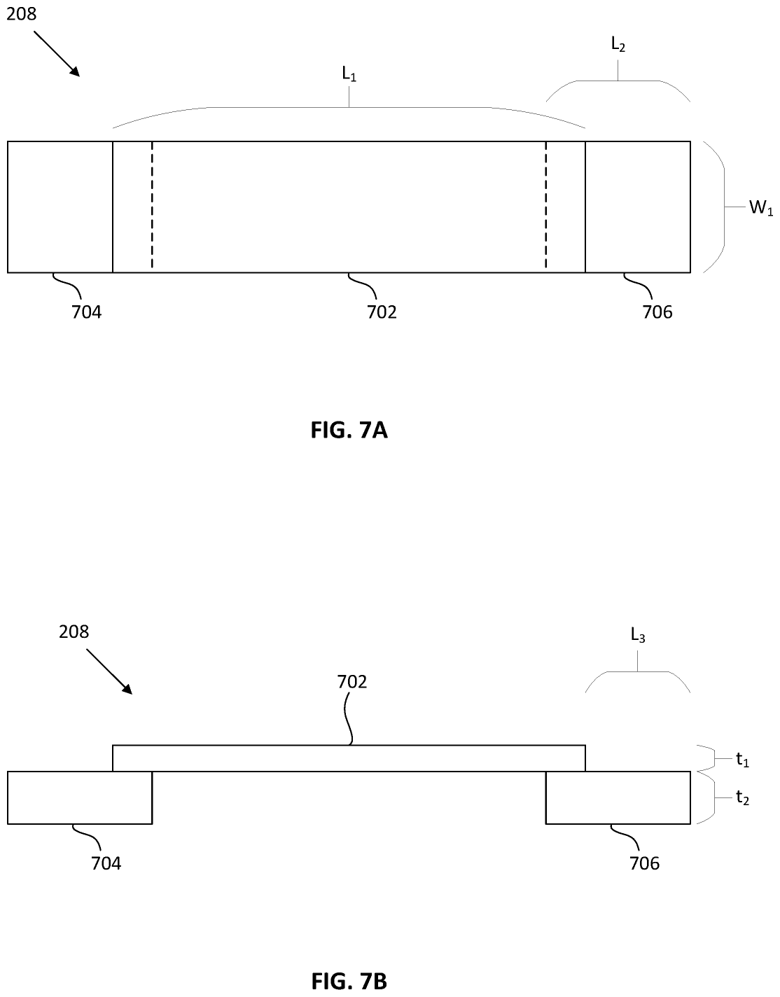

FIGS. 7A and 7B illustrate different views of a single piezoelectric cantilever 208, according to some embodiments. Piezoelectric cantilever 208 may include a body region 702, a first stage structure 704, and a second stage structure 706. Body region 702 includes one or more piezoelectric layers in a stacked configuration with one or more other materials layers (e.g., dielectric layers, doped semiconductor layers, conductive electrode layers, etc.) The bending of body region 702 during vibration of piezoelectric cantilever 208 generates the voltage that is used to provide power to other components of the aerodynamic system. In some examples, body region 702 has a length L₁ between about 30 mm and about 35 mm, and body region 702 has a width Wi between about 10 mm and about 15 mm.

According to some embodiments, each of first staging structure 704 and second staging structure 706 are coupled to a portion of body region 702 to provide additional space for attaching a mass to the free end of piezoelectric cantilever 208 and/or anchoring the fixed end of piezoelectric cantilever 208. First staging structure 704 and second staging structure 706 may be identical structures. In one example, a mass is coupled to first staging structure 704 to change the resonant frequency of piezoelectric cantilever 208 and second staging structure 706 includes one or more fasteners (e.g., screws) that anchor the fixed end of piezoelectric cantilever 208 to another fixed structure (e.g., collar 206 as illustrated in FIG. 2B). In some examples, second staging structure 706 is adhesively attached to another fixed structure or is formed with another fixed structure as one piece. According to some embodiments, each of first staging structure 704 and second staging structure 706 has a length L₂ that partially overlaps with body region 702 as indicated by the dashed lines. FIG. 7B illustrates a side view of piezoelectric cantilever 208, and also illustrates how each of first staging structure 704 and second staging structure 706 overlap with body region 702. According to some embodiments, each of first staging structure 704 and second staging structure 706 has a length L₂ between about 10 mm and about 15 mm, and a width Wi between about 10 mm and about 15 mm. According to some embodiments, each of first staging structure 704 and second staging structure 706 has a length L₃ that extends beyond body region 702 between about 7.5 mm and about 12.5 mm.

According to some embodiments, the various stacked layers that make up body region 702 have a total thickness t₁ between about 300 micrometers and about 700 micrometers. According to some embodiments, each of first staging structure 704 and second staging structure 706 has a thickness t₂ between about 1 mm and about 2 mm.

Numerous specific details have been set forth herein to provide a thorough understanding of the embodiments. It will be understood by an ordinarily-skilled artisan, however, that the embodiments may be practiced without these specific details. In other instances, well known operations, components and circuits have not been described in detail so as not to obscure the embodiments. It can be appreciated that the specific structural and functional details disclosed herein may be representative and do not necessarily limit the scope of the embodiments. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

### Further Example Embodiments

The following examples pertain to further embodiments, from which numerous permutations and configurations will be apparent.

Example 1 is an energy harvesting system configured for use on an aerodynamic system. The energy harvesting system includes a plurality of piezoelectric cantilever structures, a power conditioning circuit configured to receive electrical energy produced by the plurality of piezoelectric cantilever structures, and a storage element coupled to the power conditioning circuit and configured to store charge based on the electrical energy produced by the plurality of piezoelectric cantilever structures. The plurality of piezoelectric cantilever structures includes a first piezoelectric cantilever structure disposable within a fuselage of the aerodynamic system and oriented along a first plane, a second piezoelectric cantilever structure disposable within the fuselage of the aerodynamic system and oriented along a second plane different from the first plane, and a third piezoelectric cantilever structure disposable within the fuselage of the aerodynamic system and oriented along a third plane different from the first plane and the second plane.

Example 2 includes the subject matter of Example 1, wherein the energy harvesting system is included in the aerodynamic system, and the aerodynamic system is a projectile, and the first piezoelectric cantilever structure is disposed within the fuselage of the aerodynamic system and oriented along the first plane, the second piezoelectric cantilever structure is disposed within the fuselage of the aerodynamic system and oriented along the second plane different from the first plane, and the third piezoelectric cantilever structure is disposed within the fuselage of the aerodynamic system and oriented along the third plane different from the first plane and the second plane.

Example 3 includes the subject matter of Example 2, wherein the projectile has a cylindrical fuselage with a diameter between 2.0 inches and 3.5 inches.

Example 4 includes the subject matter of any one of Examples 1-3, wherein the storage element comprises a capacitor bank.

Example 5 includes the subject matter of any one of Examples 1-4, wherein each of the first, second, and third piezoelectric cantilever structures includes two piezoelectric layers.

Example 6 includes the subject matter of Example 5, wherein each of the two piezoelectric layers comprises lead zirconate titanate (PZT).

Example 7 includes the subject matter of any one of Examples 1-6, wherein each of the first, second, and third piezoelectric cantilever structures includes a mass coupled to a free end of each of the first, second, and third piezoelectric cantilever structures.

Example 8 includes the subject matter of any one of Examples 1-7, wherein the power conditioning circuit comprises one or more voltage regulators.

Example 9 includes the subject matter of any one of Examples 1-8, wherein the first plane is orientated at a 60 degree angle with respect to each of the second plane and the third plane, the second plane is orientated at a 60 degree angle with respect to each of the first plane and the third plane, and the third plane is orientated at a 60 degree angle with respect to each of the first plane and the second plane.

Example 10 includes the subject matter of any one of Examples 1-9, wherein each of the first, second, and third piezoelectric cantilever structures has a same length.

Example 11 includes the subject matter of Example 10, wherein the plurality of piezoelectric cantilever structures comprises a fourth piezoelectric cantilever structure disposable within a fuselage of the aerodynamic system, the fourth piezoelectric cantilever structure having a length shorter than the length of each of the first, second, and third piezoelectric cantilever structures.

Example 12 includes the subject matter of any one of Examples 1-11, wherein the power conditioning circuit and the storage element are provided together on a printed circuit board (PCB).

Example 13 includes the subject matter of Example 12, wherein the PCB includes an inertial measurement unit (IMU).

Example 14 includes the subject matter of Example 13, wherein the storage element is coupled to the IMU such that the IMU is configured to be powered by the charge stored in the storage element.

Example 15 includes the subject matter of any one of Examples 12-14, comprising a barrier, wherein the PCB is coupled to a first face of the barrier and the plurality of piezoelectric cantilever structures is arranged adjacent to a second face of the barrier opposite from the first face of the barrier.

Example 16 is a guided munition comprising the energy harvesting system of any one of Examples 1-15 and a fuselage, wherein the first piezoelectric cantilever structure is disposed within the fuselage of the guided munition and oriented along the first plane, the second piezoelectric cantilever structure disposed within the fuselage of the aerodynamic system and oriented along the second plane different from the first plane, and the third piezoelectric cantilever structure is disposed within the fuselage of the aerodynamic system and oriented along the third plane different from the first plane and the second plane.

Example 17 is an energy harvesting system configured for use on an aerodynamic system. The energy harvesting system includes a barrier disposable within a fuselage of the aerodynamic system, a plurality of piezoelectric cantilever structures arranged adjacent to a first face of the barrier, such that a primary deflection vector for each of the plurality of piezoelectric cantilever structures is parallel to the first face of the barrier, and a PCB disposed on a second face of the barrier opposite from the first face of the barrier. The PCB includes a power conditioning circuit configured to receive electrical energy produced by the plurality of piezoelectric cantilever structures, and a storage element coupled to the power conditioning circuit and configured to store charge based on the electrical energy produced by the plurality of piezoelectric cantilever structures.

Example 18 includes the subject matter of Example 17, wherein the barrier is configured to substantially fill a circular region within the fuselage.

Example 19 includes the subject matter of Example 17 or 18, wherein the plurality of piezoelectric cantilever structures comprises a first piezoelectric cantilever structure oriented along a first plane, a second piezoelectric cantilever structure oriented along a second plane different from the first plane, and a third piezoelectric cantilever structure oriented along a third plane different from the first plane and the second plane.

Example 20 includes the subject matter of Example 19, wherein the first plane is orientated at a 60 degree angle with respect to each of the second plane and the third plane, the second plane is orientated at a 60 degree angle with respect to each of the first plane and the third plane, and the third plane is orientated at a 60 degree angle with respect to each of the first plane and the second plane.

Example 21 includes the subject matter of any one of Examples 17-20, wherein the energy harvesting system is included in the aerodynamic system, and the aerodynamic system is a rocket, missile, artillery round, or unmanned aerial vehicle (UAV).

Example 22 includes the subject matter of Example 21, wherein the aerodynamic system is a rocket, missile, or artillery round that has a cylindrical fuselage with a diameter between 2.0 inches and 3.5 inches.

Example 23 includes the subject matter of any one of Examples 17-22, wherein the storage element comprises a capacitor bank.

Example 24 includes the subject matter of any one of Examples 17-23, wherein each of the plurality of piezoelectric cantilever structures includes two piezoelectric layers.

Example 25 includes the subject matter of Example 24, wherein each of the two piezoelectric layers comprises lead zirconate titanate (PZT).

Example 26 includes the subject matter of any one of Examples 17-25, wherein each of the plurality of piezoelectric cantilever structures includes a mass coupled to a free end of each of the plurality of piezoelectric cantilever structures.

Example 27 includes the subject matter of any one of Examples 17-26, wherein the power conditioning circuit comprises one or more voltage regulators.

Example 28 includes the subject matter of any one of Examples 17-27, wherein each of the plurality of piezoelectric cantilever structures has a same length.

Example 29 includes the subject matter of Example 28, wherein the plurality of piezoelectric cantilever structures is a first plurality of piezoelectric cantilever structures, and the energy harvesting system comprises a second plurality of piezoelectric cantilever structures arranged adjacent to the first face of the barrier, such that a primary deflection vector for each of the second plurality of piezoelectric cantilever structures is parallel to the first face of the barrier, wherein a length of each of the second plurality of piezoelectric cantilever structures is shorter than the length of each of the first plurality of piezoelectric cantilever structures.

Example 30 includes the subject matter of any one of Examples 17-29, wherein the PCB includes an inertial measurement unit (IMU).

Example 31 includes the subject matter of Example 30, wherein the storage element is coupled to the IMU such that the IMU is configured to be powered by the charge stored in the storage element.

Example 32 is a guided munition comprising the energy harvesting system of any one of Examples 17-31.

Example 33 is an unmanned vehicle comprising the energy harvesting system of any one of Examples 17-31.

What is claimed is:

1. An energy harvesting system configured for use on an aerodynamic system, the energy harvesting system comprising:
a plurality of piezoelectric cantilever structures comprising
a first piezoelectric cantilever structure disposable within a fuselage of the aerodynamic system and oriented along a first plane,
a second piezoelectric cantilever structure disposable within the fuselage of the aerodynamic system and oriented along a second plane different from the first plane, and
a third piezoelectric cantilever structure disposable within the fuselage of the aerodynamic system and oriented along a third plane different from the first plane and the second plane;
a power conditioning circuit configured to receive electrical energy produced by the plurality of piezoelectric cantilever structures; and
a storage element coupled to the power conditioning circuit and configured to store charge based on the electrical energy produced by the plurality of piezoelectric cantilever structures.

2. The energy harvesting system of claim 1, wherein the energy harvesting system is included in the aerodynamic system, and the aerodynamic system is a projectile, and the first piezoelectric cantilever structure is disposed within the fuselage of the aerodynamic system and oriented along the first plane, the second piezoelectric cantilever structure is disposed within the fuselage of the aerodynamic system and oriented along the second plane different from the first plane, and the third piezoelectric cantilever structure is disposed within the fuselage of the aerodynamic system and oriented along the third plane different from the first plane and the second plane.

3. The energy harvesting system of claim 2, wherein the projectile has a cylindrical fuselage with a diameter between 2.0 inches and 3.5 inches.

4. The energy harvesting system of claim 1, wherein each of the first, second, and third piezoelectric cantilever structures includes a mass coupled to a free end of each of the first, second, and third piezoelectric cantilever structures.

5. The energy harvesting system of claim 1, wherein the first plane is orientated at a 60 degree angle with respect to each of the second plane and the third plane, the second plane is orientated at a 60 degree angle with respect to each of the first plane and the third plane, and the third plane is orientated at a 60 degree angle with respect to each of the first plane and the second plane.

6. The energy harvesting system of claim 1, wherein each of the first, second, and third piezoelectric cantilever structures has a same length.

7. The energy harvesting system of claim 6, wherein the plurality of piezoelectric cantilever structures comprises a fourth piezoelectric cantilever structure disposable within a fuselage of the aerodynamic system, the fourth piezoelectric cantilever structure having a length shorter than the length of each of the first, second, and third piezoelectric cantilever structures.

8. The energy harvesting system of claim 1, wherein the power conditioning circuit and the storage element are provided together on a printed circuit board (PCB).

9. The energy harvesting system of claim 8, comprising a barrier, wherein the PCB is coupled to a first face of the barrier and the plurality of piezoelectric cantilever structures is arranged adjacent to a second face of the barrier opposite from the first face of the barrier.

10. The energy harvesting system of claim 1, wherein the storage element is coupled to an inertial measurement unit (IMU) such that the IMU is configured to be powered by the charge stored in the storage element.

11. A guided munition comprising the energy harvesting system of claim 1 and a fuselage, wherein the first piezoelectric cantilever structure is disposed within the fuselage of the guided munition and oriented along the first plane, the second piezoelectric cantilever structure disposed within the fuselage of the aerodynamic system and oriented along the second plane different from the first plane, and the third piezoelectric cantilever structure is disposed within the fuselage of the aerodynamic system and oriented along the third plane different from the first plane and the second plane.

12. An energy harvesting system configured for use on an aerodynamic system, the energy harvesting system comprising:
a barrier disposable within a fuselage of the aerodynamic system;
a plurality of piezoelectric cantilever structures arranged adjacent to a first face of the barrier, such that a primary deflection vector for each of the plurality of piezoelectric cantilever structures is parallel to the first face of the barrier; and
a PCB disposed on a second face of the barrier opposite from the first face of the barrier, the PCB comprising
a power conditioning circuit configured to receive electrical energy produced by the plurality of piezoelectric cantilever structures, and
a storage element coupled to the power conditioning circuit and configured to store charge based on the electrical energy produced by the plurality of piezoelectric cantilever structures.

13. The energy harvesting system of claim 12, wherein the barrier is configured to substantially fill a circular region within the fuselage.

14. The energy harvesting system of claim 12, wherein the plurality of piezoelectric cantilever structures comprises a first piezoelectric cantilever structure oriented along a first plane, a second piezoelectric cantilever structure oriented along a second plane different from the first plane, and a third piezoelectric cantilever structure oriented along a third plane different from the first plane and the second plane.

15. The energy harvesting system of claim 14, wherein the first plane is orientated at a 60 degree angle with respect to each of the second plane and the third plane, the second plane is orientated at a 60 degree angle with respect to each of the first plane and the third plane, and the third plane is orientated at a 60 degree angle with respect to each of the first plane and the second plane.

16. The energy harvesting system of claim 12, wherein the energy harvesting system is included in the aerodynamic system, and the aerodynamic system is a rocket, missile, artillery round, or unmanned aerial vehicle (UAV).

17. The energy harvesting system of claim 12, wherein each of the plurality of piezoelectric cantilever structures includes a mass coupled to a free end of each of the plurality of piezoelectric cantilever structures.

18. The energy harvesting system of claim 12, wherein each of the plurality of piezoelectric cantilever structures has a same length.

19. The energy harvesting system of claim 18, wherein the plurality of piezoelectric cantilever structures is a first plurality of piezoelectric cantilever structures, and the energy harvesting system comprises a second plurality of piezoelectric cantilever structures arranged adjacent to the first face of the barrier, such that a primary deflection vector for each of the second plurality of piezoelectric cantilever structures is parallel to the first face of the barrier, wherein a length of each of the second plurality of piezoelectric cantilever structures is shorter than the length of each of the first plurality of piezoelectric cantilever structures.

20. The energy harvesting system of claim 12, wherein the storage element is coupled to an inertial measurement unit (IMU) such that the IMU is configured to be powered by the charge stored in the storage element.
